(19) United States
(12) Patent Application Publication
(10) Pub. No.: US 2008/0014693 A1
(43) Pub. Date: Jan. 17, 2008

(54) SILICON CARBIDE VERTICAL MOSFET DESIGN FOR FAST SWITCHING APPLICATIONS

(75) Inventor: Kevin Sean Matocha, Rexford, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/456,901

(22) Filed: Jul. 12, 2006

(51) Int. Cl. H01L 21/8244

(52) U.S. Cl. 438/238

(57) ABSTRACT

A vertical MOSFET device includes a well region of a first conductivity type formed within a surface of a substrate of a second conductivity type opposite the first conductivity type. A doped source region of the second conductivity type is formed within the well region. A plurality of highly doped regions, with respect to the well region of the first conductivity type, are disposed within an outer perimeter of the doped source region, and away from a concentric middle point with respect to the well region and doped source region.

### STATEMENT OF GOVERNMENT INTEREST

This invention was made with Government support under Contract No. FA8650-05-C-7201 awarded by the US Air Force Research Laboratory/Defense Advanced Research Projects Agency (DARPA). The Government has certain rights in this invention.

### BACKGROUND OF THE INVENTION

The invention relates generally to power semiconductor switching devices and, more particularly, to a silicon carbide vertical MOSFET design having improved well pinch resistance for high speed switching applications.

Silicon carbide (SiC) is a wide band gap material having a maximum breakdown electric field larger than that of silicon by about one order of magnitude. Thus, SiC has been considered as an advantageous material for use in the manufacture of next generation power semiconductor devices. Such devices include, for example, Schottky diodes, thyristors and vertical MOSFETs (metal oxide semiconductor field effect transistors).

Most power MOSFETs have a different structure than commonly known “lateral” MOSFETs, in that their structure is vertical and not planar. With a planar structure, the current and breakdown voltage ratings of the MOSFET are both function of the channel dimensions (respectively width and length of the channel), resulting in inefficient use of the device real estate. With a vertical structure, the voltage rating of the transistor is a function of the doping and thickness of the epitaxial layer, while the current rating is a function of the channel periphery. This makes it possible for the transistor to sustain both high blocking voltage and high current within a compact piece of semiconductor.

One problem associated with vertical MOSFETs (for example in an N-type vertical device) is that the P-well “pinch resistor” that exists underneath the N+ source region effectively limits the voltage slew rate (dV/dt) that the device can withstand. As the drain voltage is changed abruptly, the P-well to drift-region capacitance is rapidly charged through the P-well pinch resistor below the N+ source. At high dV/dt rates, the voltage drop across the P-well pinch resistor can be sufficient to turn on the parasitic bipolar transistor formed by the source, P-well and drift regions. In vertical MOSFETs, this effect is known as “second breakdown,” which limits device high-speed performance. In other words, if the termination is properly designed, second breakdown within the device cells can limit the maximum dV/dt that the device can withstand.

Previously, the pinch resistor problem has been addressed by providing a retrograde doping profile in the P-well, with a higher doping at the bottom of the well and a reduced doping at the top of the well near the channel. Although this approach provides more carriers (holes) and thus reduces the resistance, it is ultimately limited with respect to how much of a dopant gradient can be introduced at the bottom of the well through implantation. Accordingly, it would desirable to be able to decrease well pinch resistance in a manner that overcomes the above disadvantages.

### BRIEF DESCRIPTION OF THE INVENTION

The above and other drawbacks and deficiencies of the prior art may be overcome or alleviated by an embodiment of a vertical MOSFET device, including a well region of a first conductivity type formed within a surface of a substrate of a second conductivity type opposite the first conductivity type. A doped source region of the second conductivity type is formed within the well region. A plurality of highly doped regions, with respect to the well region of the first conductivity type, are disposed within an outer perimeter of the doped source region, and away from a concentric middle point with respect to the well region and doped source region.

In another embodiment, a vertical MOSFET device includes a well region of a first conductivity type formed within a surface layer of a drift layer of a second conductivity type opposite the first conductivity type. A doped source region of the second conductivity type is formed within the well region. A gate electrode is formed on a gate insulating film, and over a portion of the well region that is interposed between the doped source region and an exposed surface portion of the drift layer. A source electrode formed in contact with both the source region and the well region, and a drain electrode is formed in contact with a rear surface of a doped drain region of the second conductivity type. A plurality of highly doped regions, with respect to the well region of the first conductivity type, are configured to enhance ohmic contact between the source electrode and the well region. Each of said plurality of highly doped regions is disposed within an outer perimeter of the doped source region, and away from a concentric middle point with respect to the well region and doped source region.

In still another embodiment, a method for reducing pinch resistance in a vertical MOSFET device includes forming a well region of a first conductivity type within a surface of a substrate of a second conductivity type opposite the first conductivity type, forming a doped source region of the second conductivity type within the well region, and forming a plurality of highly doped regions, with respect to the well region of the first conductivity type. Each of said plurality of highly doped well regions is disposed within an outer perimeter of the doped source region, and away from a concentric middle point with respect to the well region and doped source region.

These and other advantages and features will be more readily understood from the following detailed description of preferred embodiments of the invention that is provided in connection with the accompanying drawings.

### BRIEF DESCRIPTION OF THE DRAWINGS

FIG. 1 is a partial cross sectional view of an N-type, SiC vertical MOSFET cell.

FIG. 2 is an equivalent circuit diagram of the MOSFET cell of FIG. 1, illustrating the parasitic capacitances, P-well pinch resistance and parasitic bipolar transistor associated therewith at high voltage slew rates.

FIG. 3 is a top view of a portion of the MOSFET cell of FIG. 1, particularly illustrating the geometric relationship between the P-well, N+ source region, P+ region and ohmic source contact.

FIGS. 4 through 9 illustrate top views of various exemplary embodiments of a power MOSFET having reduced P-well pinch resistance.

### DETAILED DESCRIPTION OF THE INVENTION

Embodiments of the invention disclosed herein include a design layout for SiC MOSFETs which minimizes the P-well pinch resistor length (for an N-channel device), thus increasing the dV/dt capability of the SiC MOSFET. Briefly stated, an exemplary N-type vertical MOSFET is formed so as to have a plurality of P+ regions (as opposed to a single P+ region) formed within the outer perimeter of the N+ source region. Moreover, the plurality of P+ regions are disposed outwardly with respect to a middle point of the concentrically disposed P-well, N+ source and ohmic contact regions, so as to reduce the distance between the outer edges of the P+ regions and the N+ source regions, while still allowing for the P-well to be shorted to the source.

It will be appreciated that although the exemplary embodiments described herein are presented in terms of an N− channel device, the disclosed principles are equally applicable to devices of opposite polarity (i.e., P-channel devices). Thus, in a general sense, a source region is formed within a well of opposite conductivity type, and the P+ regions described herein represent more highly doped areas of the P-well regions. Accordingly, for a P-type MOSFET, the well region would be N-type, the source region would be P-type, and the multiple (more highly doped) well regions would be N+ regions.

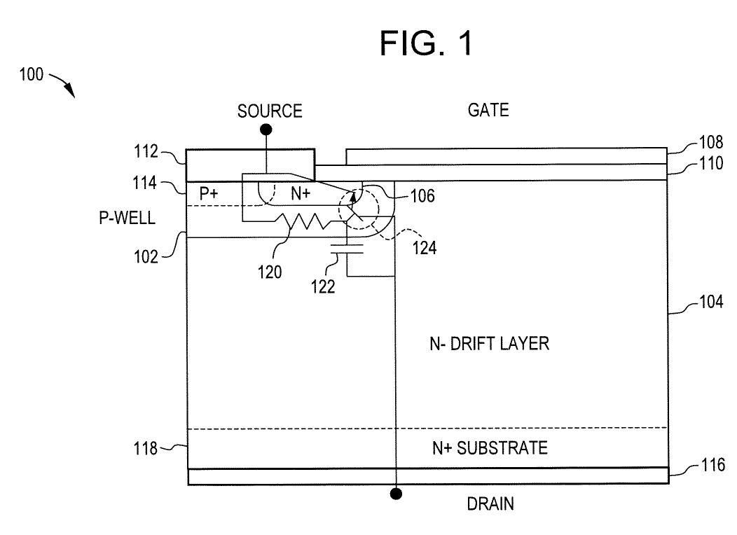

Referring initially to FIG. 1, a partial cross sectional view of an N-type, SiC vertical MOSFET cell 100 is illustrated. In an actual power MOSFET device, several of such cells 100 would be connected in parallel. As is shown in FIG. 1, the vertical MOSFET cell 100 includes a P-well region 102 formed within a surface layer of an N− drift layer 104, and an N+ source region 106 formed within the P-well region 102. A gate electrode 108 is formed on a gate insulating film 110, and over a portion of the P-well region 102 interposed between the N+ source region 106 and an exposed surface portion of the N− drift layer 104. In addition, a source electrode 112 is formed in contact with the surface of both the N+ source region 106 and the P-well region 102. As shown, a more highly doped P+ region 114, located at the top of the P-well region 102, enhances ohmic contact between the source electrode 112 and the P-well region 102. MOSFET 100 further includes a drain electrode 116 formed in contact with the rear surface of an N+ drain region 118.

In operation of the vertical MOSFET 100, a positive voltage applied to the gate electrode 108 induces an inversion layer in the surface of the P-well 102 directly beneath the gate insulating film 110, such that current flows between the source electrode 112 and drain electrode 116 (and through the N− drift layer 104). If the positive voltage to the gate electrode 108 is removed, the inversion layer beneath the gate insulating film 110 in the P-well 102 disappears and a depletion layer spreads out, thereby blocking current flow through the P-well 102.

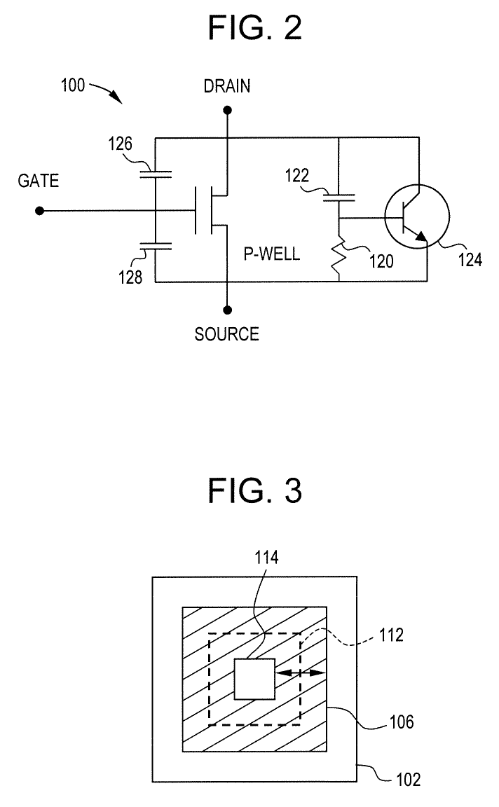

As indicated above, a resulting P-well pinch resistor (schematically represented by 120 in FIG. 1) beneath the N+ source region 106 limits the voltage slew rate that the device 100 can withstand. If the drain voltage is rapidly changed, the P-well to drift region capacitance (schematically represented by 122 in FIG. 1) is rapidly charged through the P-well pinch resistor 120. In turn, the voltage drop across the P-well pinch resistor 120 (at sufficiently high dV/dt rates) can be sufficient to turn on the parasitic bipolar transistor 124 formed by the N+ source 106, P-well 102 and drift layer 104 regions. FIG. 2 is an equivalent circuit diagram of the MOSFET 100 of FIG. 1, illustrating the P-well pinch resistor 120, P-well to drift region capacitance 122 and parasitic bipolar transistor 124, as well as the gate-to-drain capacitance 126 and the gate-to-source capacitance 128.

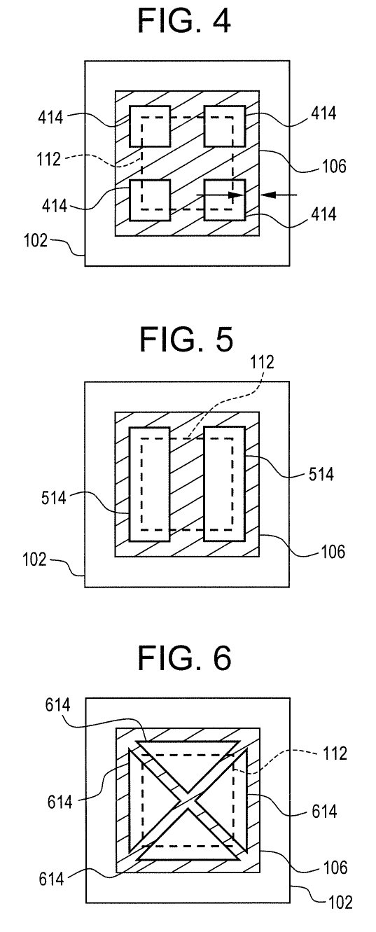

As also indicated above, the magnitude of the P-well pinch resistance 120 depends upon the distance between the outer edge of the P+ contact region 114 and the channel (i.e., the outer edge of the N+ source region 106. FIG. 3 is a top view of a portion of the MOSFET 100 of FIG. 1, particularly illustrating the geometric relationship between the P-well region 102, N+ source region 106, P+ region 114 and ohmic source contact 112. As can be seen, each of the regions shown in FIG. 3 is generally square shaped, having a common concentric point. The distance between the outer edge of the P+ region 114 and the outer edge of the N+ source region 106 determines the pinch resistance. Thus, in order to reduce the magnitude of the pinch resistance (and thus the voltage drop thereacross), the distance between the outer edge of the P+ region 114 and the outer edge of the N+ source region 106 may be decreased.

However, a review of the geometry of the configuration of the various regions of MOSFET 100 in FIG. 3 reveals the difficulty in doing so with just a single P+ region 114. On one hand, by simply relocating the P+ region 114 away from the concentric or common middle point and toward one of the outer edges of the N+ source region 106, the distance with respect to the opposite outer edge of the N+ source region 106 is increased. Such a simple relocation of the single P+ region 104 away from the concentric point can thus actually increase pinch resistance. On the other hand, simply increasing the area of the P+ region 104 (so that its outer edges approach the outer edges of the N+ source region 106) inhibits the ability of the ohmic source contact electrode 112 to electrically connect the N+ source region 106 to the P-well 102.

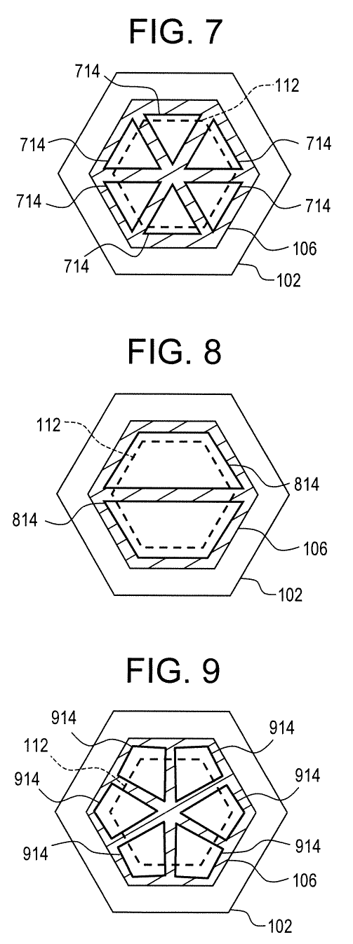

Accordingly, FIGS. 4 through 9 illustrate various exemplary embodiments of a vertical MOSFET, in which the three-dimensional structure of the device is modified to reduce pinch resistance. As opposed to the device of FIG. 3, the exemplary embodiments utilize a plurality of P+ regions formed within the P-well. In so doing, the individual P+ regions may each be disposed outward with respect to the concentric middle point of the P-well, and closer to the outer edges of the N+ source region. Further, the size and location of the individual P+ regions are selected such that the ohmic source contact electrode is still able to adequately overlap both the P+ regions and the N+ source region.

As particularly illustrated in FIG. 4, there are a total of four P+ regions 414 formed with in the P-well 102. Because there are multiple such P+ regions 414, each may be disposed away from the concentric point of the P-well 102 and closer to the outer edge of the N+ source region 106, thereby reducing the P-well pinch resistance. It will further be noted that in disposing the P+ regions 414 in closer proximity to the outer edges of the N+ source region 106 than with respect to the device of FIG. 3, the ohmic source electrode 112 overlaps only a portion of each of the P+ regions 414. While FIG. 4 depicts the P+ regions 414 located beneath the corners of the ohmic source electrode 112, they could alternatively be located beneath the midpoints of the side edges of the ohmic source electrode 112 (i.e., rotated with respect to the view in FIG. 4).

It will further be appreciated that a different number and shape of P+ regions can be used, so long as there are multiple P+ regions disposed away from the concentric middle point of the P-well. For instance, FIG. 5 illustrates an alternative embodiment in which two rectangular shaped P+ regions 514 are disposed away from the concentric middle point of the P-well 102, and with the outer edges thereof in proximity to the outer edges of the N+ source region 106. In addition, the embodiment of FIG. 6 illustrates that the shapes of the P+ regions 614 (triangular) need not coincide with the shapes of the P-well 102, N+ source region 106 and ohmic source electrode 112.

Finally, FIGS. 7-9 illustrate still further embodiments of vertical MOSFETs with improved pinch resistance. The exemplary embodiments depicted therein demonstrate that different shapes (besides square) are also contemplated for the P-well 102, N+ source region 106 and ohmic source electrode 112. For example, the concentric P-well 102, N+ source region 106 and ohmic source electrode 112 are depicted as hexagonal in shape in FIGS. 7-9. In the embodiment of FIG. 7, the (six) P+ regions 714 are triangular in shape. In FIG. 8, the two P+ regions 814 are trapezoidal in shape, and in FIG. 9, the P+ regions 914 are of a general polygon configuration. Moreover, it is further contemplated that multiple P+ regions within an individual MOSFET cell may have different shapes with respect to one another.

It should be noted that although any number of shapes are contemplated herein, as a practical matter, the complexities of the lithography steps used in forming the various regions would likely dictate the ultimate nature and shape of the device regions themselves.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A vertical MOSFET device, comprising:
a well region of a first conductivity type formed within a surface of a substrate of a second conductivity type opposite the first conductivity type;
a doped source region of the second conductivity type formed within the well region; and
a plurality of highly doped regions, with respect to the well region of the first conductivity type, wherein each of said plurality of highly doped regions is disposed within an outer perimeter of the doped source region, and away from a concentric middle point with respect to the well region and doped source region.

2. The device of claim 1, wherein the well region is P-type, the doped source region is N+ type, and the plurality of highly doped regions are P+ regions.

3. The device of claim 2, wherein the plurality of P+ regions are disposed in a manner such that an ohmic source electrode overlaps only a portion of each of the P+ regions.

4. The device of claim 2, wherein the shape of the plurality of P+ regions is substantially the same as the shape of the well region and doped source region.

5. The device of claim 2, wherein the shape of the plurality of P+ regions is different from the shape of the well region and doped source region.

6. The device of claim 1, wherein the substrate comprises SiC.

7. A vertical MOSFET device, comprising:
a well region of a first conductivity type formed within a surface layer of a drift layer of a second conductivity type opposite the first conductivity type;
a doped source region of the second conductivity type formed within the well region;
a gate electrode formed on a gate insulating film, and over a portion of the well region that is interposed between the doped source region and an exposed surface portion of the drift layer;
a source electrode formed in contact with both the source region and the well region, and a drain electrode formed in contact with a rear surface of a doped drain region of the second conductivity type; and
a plurality of highly doped regions, with respect to the well region of the first conductivity type, the plurality of highly doped regions configured to enhance ohmic contact between the source electrode and the well region;
wherein each of said plurality of highly doped regions is disposed within an outer perimeter of the doped source region, and away from a concentric middle point with respect to the well region and doped source region.

8. The device of claim 7, wherein the well region is P-type, the doped source and drain regions are N+ type, the drift layer is N− type, and the plurality of highly doped regions are P+ regions.

9. The device of claim 8, wherein the plurality of P+ regions are disposed in a manner such that an ohmic source electrode overlaps only a portion of each of the P+ regions.

10. The device of claim 8, wherein the shape of the plurality of P+ regions is substantially the same as the shape of the well region and doped source region.

11. The device of claim 8, wherein the shape of the plurality of P+ regions is different from the shape of the well region and doped source region.

12. The device of claim 7, wherein the drift layer comprises SiC.

13. A method for reducing pinch resistance in a vertical MOSFET device, the method comprising:
forming a well region of a first conductivity type within a surface of a substrate of a second conductivity type opposite the first conductivity type;
forming a doped source region of the second conductivity type within the well region; and
forming a plurality of highly doped regions, with respect to the well region of the first conductivity type, wherein each of said plurality of highly doped well regions is disposed within an outer perimeter of the doped source region, and away from a concentric middle point with respect to the well region and doped source region.

14. The method of claim 13, wherein the well region is P-type, the doped source region is N+ type, and the plurality of highly doped regions are P+ regions.

15. The method of claim 14, wherein the plurality of P+ regions are disposed in a manner such that an ohmic source electrode overlaps only a portion of each of the P+ regions.

16. The method of claim 14, wherein the shape of the plurality of P+ regions is substantially the same as the shape of the well region and doped source region.

17. The method of claim 14, wherein the shape of the plurality of P+ regions is different from the shape of the well region and doped source region.

18. The method of claim 13, wherein the substrate comprises SiC.
